(19) United States
(12) Patent Application Publication
(10) Pub. No.: US 2020/0208264 A1
(43) Pub. Date: Jul. 2, 2020

(54) SEMICONDUCTOR PROCESSING APPARATUS AND CONTROL METHOD THEREOF

(71) Applicant: Yangtze Memory Technologies Co., Ltd., Wuhan City (CN)

(72) Inventors: Hao PENG, Wuhan City (CN); Zhao LI, Wuhan City (CN); Hongbin ZHU, Wuhan City (CN); Xianjin WAN, Wuhan City (CN); Yuan LI, Wuhan City (CN); Feng ZHOU, Wuhan City (CN); Kai HU, Wuhan City (CN); Jun WEI, Wuhan City (CN); Xiangying CAI, Wuhan City (CN); Yao HU, Wuhan City (CN)

(21) Appl. No.: 16/351,545

(22) Filed: Mar. 13, 2019

Related U.S. Application Data
(63) Continuation of application No. PCT/CN2019/070104, filed on Jan. 2, 2019.

(51) Int. Cl. C23C 16/455; C23C 16/52; G08B 21/18

(52) U.S. Cl. CPC C23C 16/45544; G08B 21/18; C23C 16/52

(57) ABSTRACT

This invention relates to a semiconductor processing apparatus and a control method thereof. The semiconductor processing apparatus includes a processing chamber including two or more reaction regions. Each of the reaction regions includes an independent gas path module. The control method includes: cycle periods of introducing gas into the reaction regions are synchronized during the semiconductor processing. The semiconductor processing apparatus and the control method thereof of this invention can control the cycle periods of the reaction gas introduced into the reaction regions to be in consistent, so that the gas introduced into different reaction regions is the same at the same time, and the interference of the gas between the reaction regions is avoided, thereby improving the product yield.

### CROSS REFERENCE TO RELATED APPLICATIONS

This application is a continuation of International Application No. PCT/CN2019/070104 filed on Jan. 2, 2019, which is incorporated herein by reference in its entirety.

### BACKGROUND OF THE INVENTION

### 1. Field of the Invention

The present disclosure relates to a semiconductor apparatus, and more particularly to a semiconductor apparatus and a control method thereof.

### 2. Description of the Prior Art

Deposition, etching, and other processes are often used in the conventional semiconductor wafer processing process, and various reaction gases are required to be introduced into the reaction chamber. For example, the atomic layer deposition (ALD) process is capable of forming a film with higher uniformity and has higher step coverage performance. Due to the self-limiting characteristic of the deposition process, the increased film thickness is constant in each deposition cycle, and the process of ALD takes a long time and the wafer per hour (WPH) is low.

In the prior art, more than two reaction regions are simultaneously included in one reaction chamber to improve the efficiency of semiconductor processing. Referring to FIG. 1, it is a schematic diagram of a chamber of ALD process in prior art. Four substrates 101 are disposed in the deposition chamber 100, and four wafers 102 can be processed simultaneously, thereby increasing the WPH. Since four wafers need to be processed simultaneously, reaction gases are required to be respectively introduced into each reaction region. Even if the same semiconductor processing process is performed in different reaction regions, the complete synchronization between the gases introduced in the reaction regions cannot be realized since the introduction of gases in each reaction region can only be manually controlled in the prior art. In addition, even the same reaction gas is introduced into the reaction regions simultaneously at the beginning of the process, as a plurality of gases are sequentially introduced during the process, the reaction gases introduced into different reaction regions will finally be different at a certain moment due to the poor synchronization of manual control. Accordingly, the problem of cross interference between gases indifferent reaction regions occurs, thereby affecting the performance of semiconductor processing.

Therefore, the cross interference of the reaction gases between the reaction regions is an urgent problem to be solved at present.

### SUMMARY OF THE INVENTION

To solve the above technical problem, the present invention provides a control method of a semiconductor processing apparatus to avoid the interference between reaction gases in the reaction regions.

The present invention provides a control method of a semiconductor processing apparatus, the semiconductor processing apparatus includes a processing chamber including two or more reaction regions, each of the reaction regions comprises a gas path module, and a plurality of cycle periods of introducing gas into the reaction regions are synchronized during a semiconductor processing.

In some embodiments, each of the reaction regions is used for performing a same semiconductor processing process.

In some embodiments, each of the cycle periods of the gas includes a preparation time, a time of introducing the gas into the reaction region, and a tail gas processing time in the semiconductor processing; a difference between the cycle periods of the gas in the reaction regions is compensated by adjusting the preparation time and the tail gas processing time.

In some embodiments, a method of introducing a same gas into each of the reaction regions at a same time includes: synchronously sending control signals to the gas path modules of the reaction regions.

In some embodiments, each of the gas path modules includes a plurality of gas supply pipelines for transmitting different gases, and a valve is disposed on each of the gas supply pipelines; sending the control signals identical to each other synchronously to the valves on the gas supply pipelines which correspond to the reaction regions.

In some embodiments, a physical isolation member is disposed between the reaction regions to realize gas isolation between the reaction regions during the semiconductor processing.

In some embodiments, the physical isolation member includes a liftable partition.

In some embodiments, the control method of the semiconductor processing apparatus further includes: detecting whether the gas introduced into each of the reaction regions is identical, and alarming and stopping an operation of the semiconductor processing apparatus when the gas introduced into each of the reaction regions is different.

In some embodiments, an alarm is sent out and an operation of the semiconductor processing apparatus is stopped when the cycle periods of the gas in the reaction regions are inconsistent.

An embodiment of the present invention further provides a semiconductor processing apparatus including: a processing chamber including two or more reaction regions, wherein each of the reaction regions includes a gas path module; and a control module connected to the gas path module of each of the reaction regions, wherein the control module is used for synchronizing a plurality of cycle periods of introducing gas into the reaction regions during a semiconductor processing.

In some embodiments, each of the reaction regions is used for performing a same semiconductor processing process.

In some embodiments, each of the cycle periods of the gas includes a preparation time, a time of introducing the gas into the reaction region, and a tail gas processing time in the semiconductor processing; a difference between the cycle periods of the gas in the reaction regions is compensated by adjusting the preparation time and the tail gas processing time by the control module.

In some embodiments, the control module is connected to the gas path module of each of the reaction regions, and synchronously sending control signals to the gas path modules of the reaction regions.

In some embodiments, each of the gas path modules includes a plurality of gas supply pipelines for transmitting different gases, and a valve is disposed on each of the gas supply pipelines; the control module is connected to a control end of the valve of each of the gas supply pipelines and used for synchronously sending the control signals identical to each other to the valves on the gas supply pipelines which correspond to the reaction regions.

In some embodiments, the semiconductor processing apparatus further includes a physical isolation member disposed between the reaction regions, wherein the physical isolation member is used for realizing gas isolation between the reaction regions during the semiconductor processing.

In some embodiments, the physical isolation member includes a liftable partition.

In some embodiments, the semiconductor processing apparatus further includes a detection module used for detecting whether the gas introduced into each of the reaction regions is identical, and alarming and stopping an operation of the semiconductor processing apparatus when the gas introduced into each of the reaction regions is different.

In some embodiments, the detection module is further used for alarming and stopping the operation of the semiconductor processing apparatus when an inconsistency of the cycle periods of the gas in the reaction regions is detected.

The semiconductor processing apparatus and the control method thereof of the present invention can control the cycle periods of the reaction gas introduced into the reaction regions to be in consistent, so that the gas introduced into different reaction regions is the same at the same time, and the interference of the gas between the reaction regions is avoided, thereby improving the product yield.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic structural diagram of a semiconductor processing apparatus of the prior art of the present invention.

FIG. 2 is a schematic block diagram of a semiconductor processing apparatus according to an embodiment of the present invention.

FIG. 3 is a timing diagram of introducing B₂H₆ gas into each reaction region in an embodiment of the present invention.

FIG. 4 is a schematic diagram illustrating thicknesses and resistances of WN thin films formed by ALD process by adjusting tail gas processing times in the embodiment of the present invention.

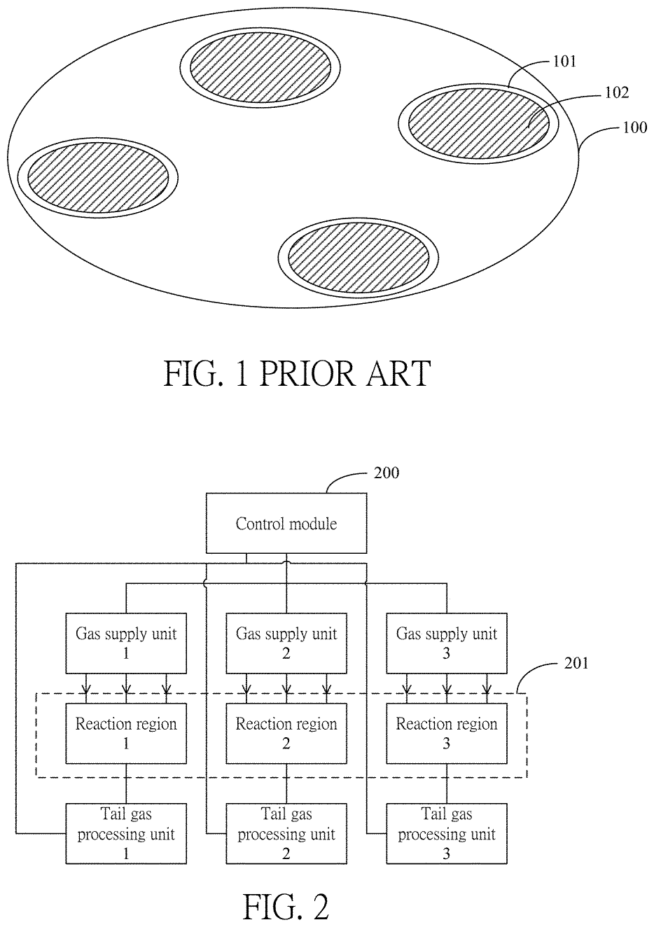

### DETAILED DESCRIPTION

An embodiment of a semiconductor processing apparatus and a control method thereof of the present invention is detailed below with reference to the accompanying drawings.

Referring to FIG. 2, it is a schematic block diagram of a semiconductor processing apparatus according to an embodiment of the present invention.

The semiconductor processing apparatus of the present invention includes at least two reaction regions, and the semiconductor processing process can be performed to one wafer in each of the reaction regions. Therefore, at least two wafers can be processed simultaneously in the semiconductor processing apparatus.

In this embodiment, the semiconductor processing apparatus includes a processing chamber 201. The processing chamber 201 includes three reaction regions, which are a reaction region 1, a reaction region 2, and a reaction region 3. Each of the reaction regions includes an independent gas path module. The semiconductor processing apparatus further includes an air curtain module used for forming the air curtain between the reaction regions to reduce interference between the reaction regions during the semiconductor processing.

The reaction region 1, the reaction region 2, and the reaction region 3 are all disposed inside the same processing chamber 201, and each of them includes a substrate used for placing the wafer and a supporting structure corresponding to the substrate and the like. Each of the reaction regions is used for performing the same semiconductor processing process, and therefore identical reaction gas is required to be introduced into each of the reaction regions.

Each of the gas path modules includes a gas supply unit and a tail gas processing unit. The gas supply unit 1 is used for supplying the reaction gas into the reaction region 1, the gas supply unit 2 is used for supplying the reaction gas into the reaction region 2, and the gas supply unit 3 is used for supplying the reaction gas into the reaction region 3. The tail gas processing unit 1 is used for processing by-products and the surplus reaction gas after the reaction is completed in the reaction region 1, the tail gas processing unit 2 is used for processing by-products and the surplus reaction gas after the reaction is completed in the reaction region 2, and the tail gas processing unit 3 is used for processing by-products and the surplus reaction gas after the reaction is completed in the reaction region 3.

The semiconductor processing apparatus further includes a control module 200 connected to the gas path module of each of the reaction regions, and the control module 200 is used for synchronizing a plurality of cycle periods of introducing the gas into the reaction regions during the semiconductor processing. In this embodiment, the control module 200 includes two signal output ports respectively connected to the gas supply units and the tail gas processing units of the gas path modules to respectively control the gas supply units and the tail gas processing units. Specifically, the control module 200 is connected to the gas supply unit 1, the gas supply unit 2, and the gas supply unit 3 through one of the signal output ports, and control signals can be provided to the gas supply unit 1, the gas supply unit 2, and the gas supply unit 3 respectively or simultaneously. Similarly, the control module 200 is connected to the tail gas processing unit 1, the tail gas processing unit 2, and the tail gas processing unit 3 through the other one of the signal output ports, and the control signals can be provided to the tail gas processing unit 1, the tail gas processing unit 2, and the tail gas processing unit 3 respectively or simultaneously.

The control module 200 is used for synchronizing the cycle periods of introducing the gas into the reaction regions during the semiconductor processing. Each of the cycle periods of the gas includes a preparation time, a time of introducing the gas into the reaction region, and a tail gas processing time. The time which the introduced gas is being reacted is determined by the time of introducing the gas into the reaction region, and it plays a decisive role in the result of the semiconductor processing process. However, the changes of the preparation time and the tail gas processing time usually have slight influences on the result of the semiconductor processing process. The cycle period of another gas is started after the previous cycle period is over.

The control module 200 is used for controlling the gas preparation time and the time of introducing the gas into the reaction region of the gas supply unit, and also used for controlling the tail gas processing time of the tail gas treatment unit. The control module 200 respectively controls the cycle periods of the gas corresponding to the reaction region 1, the reaction region 2, and the reaction region 3 accurately through the system and internal logic control to realize the synchronization of the cycle periods of the gas in three reaction regions. In this process, when the cycle periods of the same gas in different reaction regions are different, the difference between the cycle periods of the gas in the reaction regions can be compensated by adjusting the preparation time and the tail gas processing time in the cycle period of the gas in each of the reaction regions, thereby synchronizing the cycle periods of the reaction gas in the reaction regions. Preferably, the time for introducing the same gas into the reaction regions is the same.

In this embodiment, the semiconductor processing apparatus is an atomic layer deposition (ALD) apparatus which includes three reaction regions used for depositing the WN thin film. The WN thin film is a W (tungsten) thin film doped with N (nitrogen) . For example, diborane (B₂H₆), tungsten hexafluoride (WF₆), and nitrogen trifluoride (NF₃) are required to be introduced into the reaction region in sequence. For example, each of the gas supply units is connected to the reaction region through three gas supply pipelines for respectively providing three gases (i.e. B₂H₆, WF₆, and NF₃). A valve is disposed on each of the gas supply pipelines. The control module 200 is connected to a control end of each valve and is used for controlling the on-off state of each valve. The control module 200 synchronously sending the control signals to the gas supply pipelines corresponding to the gas to synchronously open or close the corresponding gas supply pipelines.

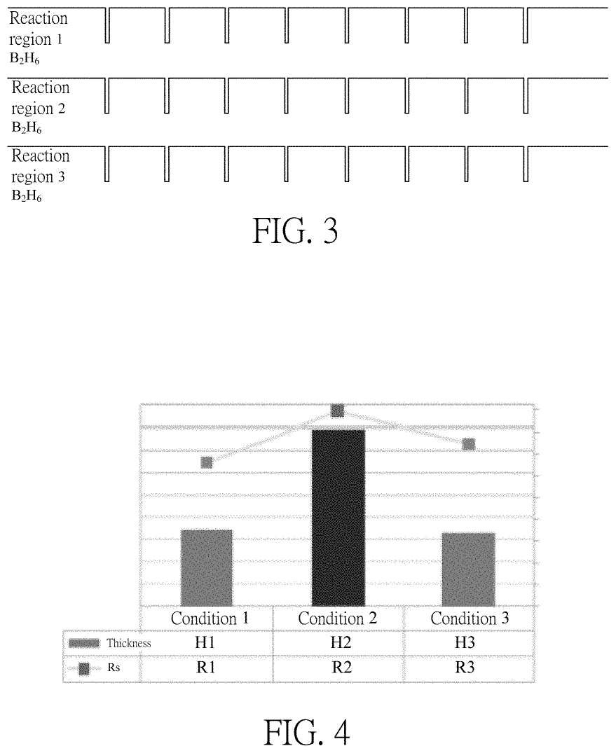

In one embodiment, the reaction region 1, the reaction region 2, and the reaction region 3 may have the same process parameters, and the cycle periods of B₂H₆, the cycle periods of WF₆, and the cycle periods of NF₃ in the reaction regions are the same. The control module 200 only needs to strictly control the synchronization of the gas supply units and the tail gas processing units, and the gas introduced into the reaction regions can be the same at any moment. Even if the reaction gas in one of the reaction regions enters other reaction regions, the deposition process in each of the reaction regions will not be affected, thereby improving the film forming quality in each of the reaction regions. The synchronization of gas delivery can be realized by synchronously sending the control signals to the valves of the gas supply pipelines. The valves of the gas supply pipelines for transmitting the same gas in the gas supply units can also communicate with each other to ensure opening or closing synchronously. As shown in FIG. 3, it is a timing diagram of introducing B₂H₆ gas into the reaction regions 1, 2, and 3. The cycle periods of B₂H₆ in the reaction regions are consistent with each other, and the times of introduction and closure are the same. Similarly, the cycle periods are the same when other gases are introduced into the reaction regions 1, 2, and 3. Therefore, no gas is introduced or the same gas is introduced into the reaction regions at any moment.

In other embodiments, the reaction region 1, the reaction region 2, and the reaction region 3 may have different process parameters. For example, the WN thin films with different thicknesses are required to be formed in the reaction region 1, the reaction region 2, and the reaction region 3, respectively.

In one embodiment, the time of introducing B₂H₆ into the reaction region 1 is less than the time of introducing B₂H₆ into the reaction region 2. The control module 200 adjusts the preparation time before B₂H₆ is introduced into the reaction region 1 based on the time when B₂H₆ is introduced into the reaction region 2 to perform the compensation of the cycle period. Accordingly, the gas supply unit 1 and the gas supply unit 2 can introduce B₂H₆ into the reaction region 1 and the reaction region 2 at the same time.

The control module 200 can prolong or shorten the preparation time and the tail gas processing time in the cycle period of each gas to keep the cycle periods of the same gas consistent among the reaction regions. By adjusting the tail gas processing time of NF₃, which is introduced before introducing B₂H₆, the cycle periods of B₂H₆ which is introduced into the reaction region 1 the reaction region 2 can be the same.

In other embodiments of the present invention, the semiconductor processing apparatus further includes a detection module used for detecting whether the gas introduced into each of the reaction regions is identical, and alarming and stopping the operation of the semiconductor processing apparatus when the gas introduced into each of the reaction regions is different. The detection module may include a gas sensor disposed in each of the reaction regions for detecting the gas introduced into the reaction region and feeding back to the control module 200. The alarm will be sent out and the operation of the semiconductor processing apparatus will be stopped when the gas introduced into each of the reaction regions is different.

In other embodiments, the detection module can also determine whether the cycle periods of each gas are consistent by referring to the process parameters of the reaction regions set before the operation of the semiconductor device. The alarm will be sent out and the operation of the semiconductor processing apparatus will be stopped when the cycle periods of the gas in the reaction regions are inconsistent.

In other embodiments, the semiconductor processing apparatus further includes a physical isolation member disposed between the reaction regions to realize gas isolation between the reaction regions. Even when the gas introduced into the reaction regions is not synchronized, the cross interference between the gases can be effectively blocked due to the physical isolation between the reaction regions. In one embodiment, the physical isolation member includes a liftable partition. The partition is lifted to form the isolation between the reaction regions after the wafer is placed into each of the reaction regions, and the partition is retracted after the semiconductor processing process.

Referring to FIG. 4, it is a schematic diagram illustrating the comparison of effects of synchronous control and asynchronous control in one embodiment of the present invention. The WN thin films are formed by the ALD processes under different conditions of the cycle period in this embodiment.

Condition 1 is that the WN thin film is formed under the condition that the gas is synchronously introduced into the reaction regions. Condition 2 is that the time of the cycle period is prolonged, but the gas synchronization control is not performed between the reaction regions. Condition 3 is that the time of the cycle period is prolonged, and the gas is simultaneously introduced into the reaction regions. It can be realized from FIG. 4 that if the time of the cycle period is prolonged but the synchronous control of the gas between the reaction regions is neglected, the thickness H2 will increase more, and at the same time, undesirable results such as the increased resistance will occur. Under the condition 1 to the condition 3, the resistance R2 of the WN thin film is larger than the resistance R1 and the resistance R3 of the WN thin films when the WN thin films have identical thickness. Comparing the results of the condition 3 and the condition 1, although the cycle period in the condition 3 is prolonged and the thickness H3 is larger than the thickness H1 of the condition 1, the resistance R1 and the resistance R3 of the WN thin films formed with the same thickness are similar due to the synchronization of the cycle periods of the gas introduced into the reaction regions.

In the ALD process, the resistance of the thin film formed in the same thickness is an important parameter, which represents the quality of the thin film. This parameter not only determines the range of the practical application of the process, but also is an important criterion for determining whether the process is abnormal. As shown in FIG. 4, the quality of the formed thin film can be effectively improved and maintained by controlling the synchronization of the cycle periods of the gas introduced into the reaction regions.

According to situations of other processes which are carried out in the reaction regions, the control of the synchronization of the cycle periods of the gas introduced into the reaction regions can also effectively improve the process effect and product yield.

The embodiment of the present invention further provides a control method of the semiconductor processing apparatus. The semiconductor processing apparatus includes a processing chamber, the processing chamber includes two or more reaction regions, each of the reaction regions includes an independent gas path module, and a plurality of cycle periods of introducing gas into the reaction regions are synchronized during a semiconductor processing.

Each of the reaction regions is used for performing the same semiconductor processing process which may have the same or different process parameters. The process parameters include the cycle period of the gas, the gas flow rate, the temperature, etc.

The cycle period of each gas includes a preparation time, a time of introducing the gas into the reaction region, and a tail gas processing time in the semiconductor processing; the difference between the cycle periods of the gas in the reaction regions is compensated by adjusting the preparation time and the tail gas processing time.

The control signals are synchronously sent to the gas path modules of the reaction regions. Specifically, each of the gas path modules includes a plurality of gas supply pipelines for transmitting different gases, and a valve is disposed on each of the gas supply pipelines; sending the control signals identical to each other synchronously to the valves on the gas supply pipelines which correspond to the reaction regions.

In other embodiments, a physical isolation member can be disposed between the reaction regions to realize the gas isolation between the reaction regions during the semiconductor processing. The physical isolation member includes a liftable partition.

During the process of the semiconductor processing, the control method further includes: detecting whether the gas introduced into each of the reaction regions is identical, and alarming and stopping the operation of the semiconductor processing apparatus when the gas introduced into each of the reaction regions is different. In another embodiment, the alarm can be sent out and the operation of the semiconductor processing apparatus can be stopped when the cycle periods of the gas in the reaction regions are inconsistent.

The above description is only the preferred embodiment of the present invention, and it should be pointed out that for a person having ordinary skill in the art, numerous modifications and alterations may be made without departing from the principles of the present invention, and these modifications and alterations should also be construed as the protection scope of the present invention.

1. A control method of a semiconductor processing apparatus, wherein the semiconductor processing apparatus comprises a processing chamber comprising two or more reaction regions, each of the reaction regions comprises a gas path module, and a plurality of cycle periods of introducing gas into the reaction regions are synchronized during a semiconductor processing.

2. The control method of the semiconductor processing apparatus of claim 1, wherein each of the reaction regions is used for performing a same semiconductor processing process.

3. The control method of the semiconductor processing apparatus of claim 1, wherein each of the cycle periods of the gas comprises a preparation time, a time of introducing the gas into the reaction region, and a tail gas processing time in the semiconductor processing; a difference between the cycle periods of the gas in the reaction regions is compensated by adjusting the preparation time and the tail gas processing time.

4. The control method of the semiconductor processing apparatus of claim 1, wherein a method of introducing a same gas into each of the reaction regions at a same time comprises: synchronously sending control signals to the gas path modules of the reaction regions.

5. The control method of the semiconductor processing apparatus of claim 4, wherein each of the gas path modules comprises a plurality of gas supply pipelines for transmitting different gases, and a valve is disposed on each of the gas supply pipelines; sending the control signals identical to each other synchronously to the valves on the gas supply pipelines which correspond to the reaction regions.

6. The control method of the semiconductor processing apparatus of claim 1, wherein a physical isolation member is disposed between the reaction regions to realize gas isolation between the reaction regions during the semiconductor processing.

7. The control method of the semiconductor processing apparatus of claim 6, wherein the physical isolation member comprises a liftable partition.

8. The control method of the semiconductor processing apparatus of claim 1, further comprising: detecting whether the gas introduced into each of the reaction regions is identical, and alarming and stopping an operation of the semiconductor processing apparatus when the gas introduced into each of the reaction regions is different.

9. The control method of the semiconductor processing apparatus of claim 1, wherein an alarm is sent out and an operation of the semiconductor processing apparatus is stopped when the cycle periods of the gas in the reaction regions are inconsistent.

10. A semiconductor processing apparatus, comprising:
a processing chamber comprising two or more reaction regions, wherein each of the reaction regions comprises a gas path module; and
a control module connected to the gas path module of each of the reaction regions, wherein the control module is used for synchronizing a plurality of cycle periods of introducing gas into the reaction regions during a semiconductor processing.

11. The semiconductor processing apparatus of claim 10, wherein each of the reaction regions is used for performing a same semiconductor processing process.

12. The semiconductor processing apparatus of claim 10, wherein each of the cycle periods of the gas comprises a preparation time, a time of introducing the gas into the reaction region, and a tail gas processing time in the semiconductor processing; a difference between the cycle periods of the gas in the reaction regions is compensated by adjusting the preparation time and the tail gas processing time by the control module.

13. The semiconductor processing apparatus of claim 10, wherein the control module is connected to the gas path module of each of the reaction regions, and synchronously sending control signals to the gas path modules of the reaction regions.

14. The semiconductor processing apparatus of claim 13, wherein each of the gas path modules comprises a plurality of gas supply pipelines for transmitting different gases, and a valve is disposed on each of the gas supply pipelines; the control module is connected to a control end of the valve of each of the gas supply pipelines and used for synchronously sending the control signals identical to each other to the valves on the gas supply pipelines which correspond to the reaction regions.

15. The semiconductor processing apparatus of claim 10, further comprising a physical isolation member disposed between the reaction regions, wherein the physical isolation member is used for realizing gas isolation between the reaction regions during the semiconductor processing.

16. The semiconductor processing apparatus of claim 15, wherein the physical isolation member comprises a liftable partition.

17. The semiconductor processing apparatus of claim 10, further comprising a detection module used for detecting whether the gas introduced into each of the reaction regions is identical, and alarming and stopping an operation of the semiconductor processing apparatus when the gas introduced into each of the reaction regions is different.

18. The semiconductor processing apparatus of claim 17, wherein the detection module is further used for alarming and stopping the operation of the semiconductor processing apparatus when an inconsistency of the cycle periods of the gas in the reaction regions is detected.
